(19) United States
(12) Patent Application Publication
(10) Pub. No.: US 2026/0269184 A1
(43) Pub. Date: Sep. 10, 2026

(54) MODULATION OF STATION VOLTAGES DURING PLASMA OPERATIONS

(71) Applicant: Lam Research Corporation, Fremont, CA (US)

(72) Inventors: David French, Fort Myers, FL (US); Yukinori Sakiyama, West Linn, OR (US)

(21) Appl. No.: 18/873,641

(22) PCT Filed: Jun. 14, 2023
(86) PCT No.: PCT/US2023/025284

§ 371 Date: Dec. 10, 2024

Related U.S. Application Data
(60) Provisional application No. 63/366,525, filed on Jun. 16, 2022.

(51) Int. Cl. H01J 37/32; H10P 72/00

(52) U.S. Cl. CPC H01J 37/32174; H01J 37/3244; H01J 37/32917; H10P 72/0421

(57) ABSTRACT

Various embodiments herein relate to systems, apparatuses, and methods for modulation of station voltages during plasma operations. In some embodiments, a system comprises: a process chamber; at least one variable reactance element operatively coupled to an un powered electrode of the process chamber; and a controller. In some embodiments, the controller is configured to determine one or more target voltages associated with one or more components. The controller may be configured to determine a value of the at least one variable reactance element based on the one or more target voltages. The controller may be configured to cause the at least one variable reactance element to have the determined value, wherein causing the at least one variable reactance element to have the determined value causes one or more voltages associated with the one or more components of the process chamber to move towards the one or more target voltages.

### INCORPORATION BY REFERENCE

A PCT Request Form is filed concurrently with this specification as part of the present application. Each application that the present application claim benefit of or priority to as identified in the concurrently filed PCT Request Form is incorporated by reference herein in its entirety and for all purposes.

### BACKGROUND

Plasma-based operations, such as plasma-enhanced chemical vapor deposition (PECVD), atomic layer deposition (ALD), atomic layer etching (ALE), or the like are often conducted in a plasma reactor that includes two electrodes that are configured to sustain a plasma in the region between the electrodes. The plasma may be ignited and/or sustained when an RF signal is provided to a powered electrode of the two electrodes.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Disclosed herein are systems, apparatuses, and methods for modulation of station voltages during plasma operations.

In some embodiments, a system if provided. The system may comprise: a process chamber configured for performing a semiconductor fabrication process comprising a plasma-based operation; at least one variable reactance element operatively coupled to an unpowered electrode of the process chamber; and a controller. The controller may be configured to determine, during or prior to performance of the plasma-based operation, one or more target voltages associated with one or more components of the process chamber. The controller may be configured to determine a value of the at least one variable reactance element based at least in part on the one or more target voltages. The controller may be configured to cause the at least one variable reactance element to have the determined value, wherein causing the at least one variable reactance element to have the determined value causes one or more voltages associated with the one or more components of the process chamber to move towards the one or more target voltages.

In some examples, the unpowered electrode of the process chamber comprises a showerhead of the process chamber, and wherein at least one variable reactance element is electrically connected to the showerhead or is disposed in a showerhead.

In some examples, the unpowered electrode of the process chamber is a pedestal of the process chamber, wherein the at least one variable reactance element is electrically connected to or is disposed in a pedestal of the process chamber.

In some examples, causing the one or more voltages associated with the one or more components of the process chamber to move towards the one or more target voltages reduces a likelihood of parasitic plasma within the process chamber.

In some examples, at least one of the one or more target voltages is a voltage associated with an unpowered showerhead of the process chamber.

In some examples, the system further comprises a pedestal configured to support a wafer undergoing the semiconductor fabrication process, and wherein at least one of the one or more target voltages is a voltage at a location proximate to a resting position of the wafer. In some examples, causing the at least one variable reactance element to have the determined value causes the voltage at the location proximate to the resting position of the wafer to be substantially lower than a voltage at the location prior to causing the at least one reactance element to have the determined value. In some examples, the system further comprises a Radio-Frequency (RF) generator operatively coupled to the pedestal.

In some examples, the at least one variable reactance element comprises a variable capacitor. In some examples, the system further comprises a stepper motor operatively coupled to the variable capacitor, and wherein the controller is configured to cause the variable capacitor to have the determined value by actuating the stepper motor. In some examples, the value of the variable capacitor is determined based on an inductance associated with the unpowered electrode.

In some examples, the at least one variable reactance element comprises a variable inductor.

In some examples, the at least one variable reactance element comprises a network configured to provide different reactances for different frequencies. In some examples, the different frequencies comprise: DC, a plurality of RF drive frequencies, a plurality of harmonics of one or more RF drive frequencies, or any combination thereof.

In some examples, the at least one variable reactance element comprises a replaceable hardware element.

In some examples, the plasma operation is a plasma-based etch operation or a plasma-based deposition operation.

In some embodiments, a method is provided. The method may comprise determining, during or prior to performance of a plasma-based operation within a process chamber, one or more target voltages associated with one or more components of the process chamber, the process chamber comprising an unpowered electrode. The method may comprise determining a value of at least one variable reactance element operatively coupled to the unpowered electrode. The method may comprise causing the at least one variable reactance element to have the determined value, wherein causing the at least one variable reactance element to have the determined value causes one or more voltages associated with the one or more components of the process chamber to move towards the one or more target voltages.

In some examples, determining the value of the at least one variable reactance element comprises utilizing the one or more target voltages as key values to a look up table to identify the value of the at least one variable reactance element that causes the one or more voltages associated with the one or more components to be within a predetermined range of the one or more target voltages.

In some examples, determining the value of the at least one variable reactance element is based on a circuit model of at least a portion of the process chamber, wherein the circuit model includes the at least one variable reactance element. In some examples, the circuit model comprises one or more circuit elements associated with a plasma formed in the process chamber. In some examples, the one or more circuit elements associated with the plasma comprise a resistor representing a plasma resistance and a capacitor representing a capacitance associated with a plasma sheath. In some examples, the at least one variable reactance element comprises a variable capacitor, and wherein the circuit model comprises the variable capacitor coupled in series to an inductor representing an inductance of the unpowered electrode. In some examples, the value of the variable capacitor is determined as a value that causes an impedance associated with the variable capacitor to substantially cancel an impedance associated with the inductor representing the inductance of the unpowered electrode.

In some examples, the unpowered electrode comprises a pedestal of the process chamber.

In some examples, the at least one variable reactance element comprises a variable inductor.

In some examples, the value of the at least one variable reactance element is determined based at least in part on plasma characteristics determined based on optical data captured from an optical sensor.

In some examples, the value of the at least one variable reactance element is determined based at least in part on plasma characteristics determined based on electrical power, voltage, current, and/or phase measurements of RF signal(s) measured within one or more regions of the process chamber or an RF power delivery system.

In some examples, the value of the at least one variable reactance element is determined based at least in part on plasma characteristics determined based on DC bias signals measured on one or more of: a powered electrode, or on the unpowered electrode.

In some examples, the value of the at least one variable reactance element is determined based at least in part on plasma characteristics determined based on electrical plasma diagnostics in the process chamber.

### BRIEF DESCRIPTION OF THE DRAWINGS

FIG. 1 is a schematic diagram of an example apparatus in accordance with some embodiments.

FIG. 2 is a schematic diagram that represents components of an apparatus configured for plasma operations as equivalent circuit elements in accordance with some embodiments.

FIG. 3 is a schematic diagram that illustrates use of a variable reactive element for modulating voltages of a station in accordance with some embodiments.

FIGS. 4A and 4B are plots that show the effect of an example variable capacitor on voltages in accordance with some embodiments.

FIG. 5 is a flowchart of an example process for modulating voltages using a variable reactive element in accordance with some embodiments.

FIG. 6 presents an example computer system that may be employed to implement certain embodiments described herein.

### DETAILED DESCRIPTION

### Terminology

The following terms are used throughout the instant specification:

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Besides semiconductor wafers, other work pieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The work piece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

### Modulation of Station Voltages During Plasma Operations

Plasma-based operations, such as plasma-enhanced chemical vapor deposition (PECVD), atomic layer deposition (ALD), atomic layer etching (ALE), or the like are often conducted in a plasma reactor that includes two electrodes that are configured to sustain a plasma in the region between the electrodes. The plasma may be ignited and/or sustained when an RF signal is provided to a powered electrode of the two electrodes. An unpowered electrode of the two electrodes, affixed to a wall of the plasma reactor, may be effectively DC grounded at relatively low RF frequencies. However, at higher RF frequencies, the unpowered electrode may develop a voltage relative to the walls of the plasma reactor. This voltage may have detrimental effects on the plasma within the reactor, such as causing parasitic plasma in regions of the reactor other than the region between the two electrodes. The detrimental effects on the plasma may create unpredictable and/or adverse conditions for, e.g., semiconductor fabrication operations, such as non-uniformity in deposition layers, non-uniformity in etched layers, etc.

Disclosed herein are techniques for modulating voltages at various regions of a station of a process chamber during and/or prior to performance of a plasma operation. In some implementations, one or more target voltages, each associated with a component of the station, are determined. Example components of the station for which target voltages may be determined include a showerhead of the station (e.g., where the target voltage is a voltage across the showerhead), a pedestal of the station (e.g., where the target voltage is in a region proximate to a top or upper surface of the pedestal where a wafer resides during processing), or the like. In some implementations, one or more variable reactance elements may be tuned to a value that drives voltages of the station toward the one or more target voltages. Target voltages may be specified in a recipe (e.g., for a particular step or portion of a recipe). By way of example, a target voltage for a region proximate an upper surface of a pedestal may be a value that minimizes parasitic plasma under the pedestal.

It should be noted that the one or more variable reactance elements may be operatively coupled to an unpowered electrode of a process station. For example, in an instance in which an RF signal is provided to a pedestal, which serves as the powered electrode, the one or more variable reactance elements may be operatively coupled to the showerhead, which serves as the unpowered electrode. As another example, in an instance in which the showerhead is the powered electrode, the one or more variable reactance elements may be operatively coupled to the pedestal.

In some embodiments, values of the one or more variable reactance elements that will drive voltages toward the one or more target voltages may be determined using a look up table. For example, the one or more target voltages may be provided as keys to the look up table, where the values of the variable reactance elements are identified from the values of the look up table likely to drive voltages to get close to or substantially match the one or more target voltages. In some implementations, values of the one or more variable reactance elements may be determined based at least in part on near real-time or prevailing plasma characteristics of a plasma in the station. In some implementations, the plasma characteristics may be based on optical data, e.g., from an optical sensor positioned to capture images of plasma within the station. In some implementations, the plasma characteristics may be determined based on electrical power, voltage, current, and/or phase measurements of one or more RF signals measured at any region (or at any multiple regions) associated with or within the process chamber apparatus. In some implementations, the plasma characteristics may be determined based on DC bias signals measured on a powered electrode and/or an unpowered electrode. In some implementations, the plasma characteristics may be determined based on electrical plasma diagnostics run in the process chamber. Note that, in some embodiments, plasma characteristics may be determined based on a combination of one or more of the techniques described above.

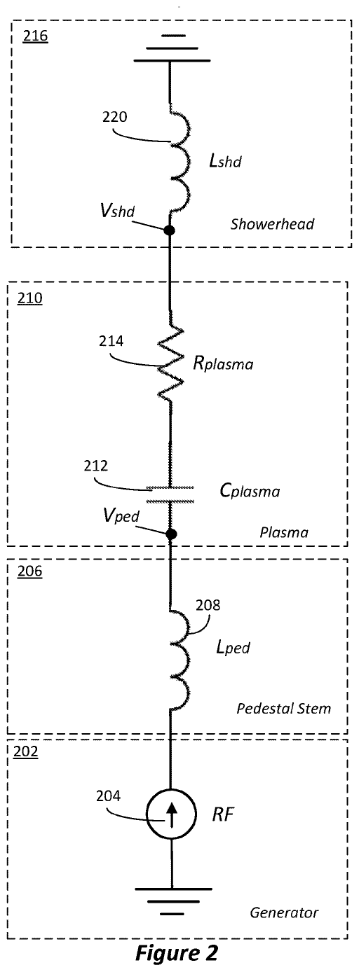

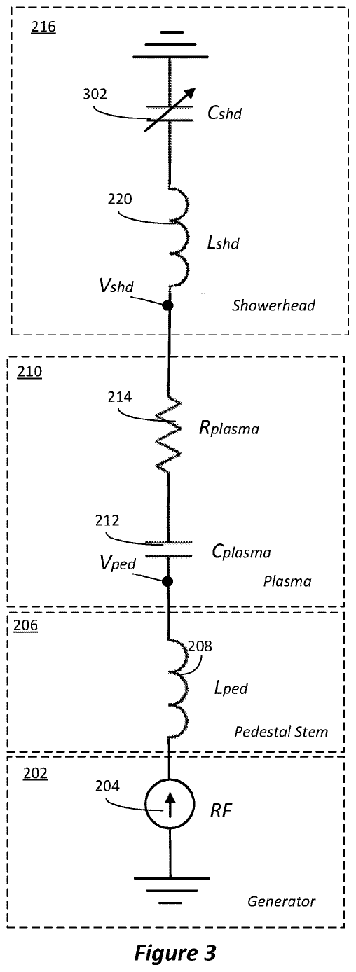

It should be understood that a recipe that is used for performing a plasma operation may constrain various process conditions, such as RF signals utilized to generate or maintain a plasma, process gases, flow rates, pressures, temperatures, or the like. These process conditions may in turn affect voltages at various regions of the station. For example, as will be explained in more detail below in connection with FIGS. 2 and 3, plasma characteristics may affect voltages across a showerhead and/or proximate to a pedestal, where the plasma characteristics are driven by the process conditions. Accordingly, the techniques described herein may be utilized to modulate voltages after other process conditions are set for a particular recipe step. In other words, the use of a variable reactance element associated with an unpowered electrode of a station to modulate voltages may introduce an additional variable that may be tuned after process conditions have been set.

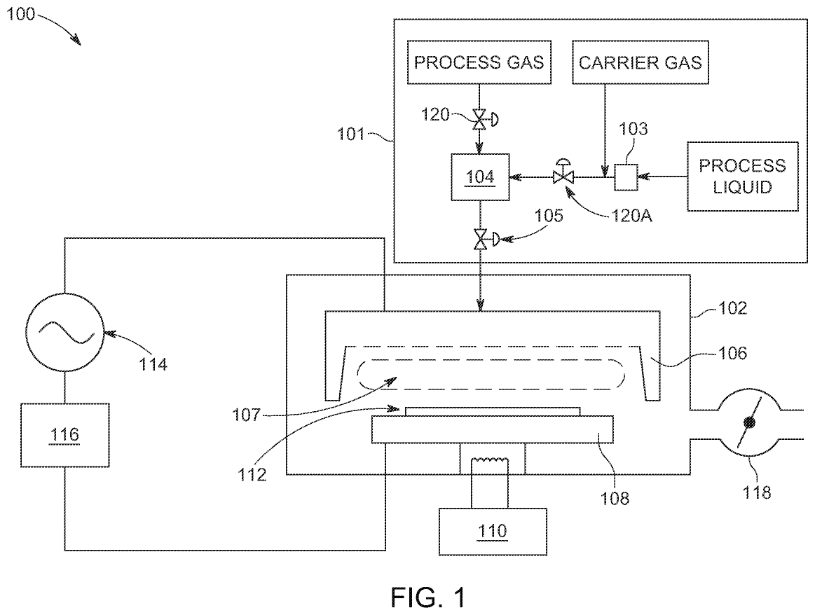

FIG. 1 shows a fabrication tool denoted as substrate processing apparatus 100. Apparatus 100 may be configured for depositing films on or over a semiconductor substrate utilizing any number of processes. For example, apparatus 100 may be adapted for performing, in particular, PECVD, ALD, or ALE.

Processing apparatus 100 of FIG. 1 may employ a single process station 102 of a process chamber with a single substrate holder 108 (e.g., a pedestal) in an interior volume, which may be maintained under vacuum by a vacuum pump 118. A showerhead 106 and a gas delivery system 101, which are fluidically coupled to the process chamber, may permit the delivery of film precursors, for example, as well as carrier and/or purge and/or process gases, secondary reactants, etc.

In FIG. 1, gas delivery system 101 includes a mixing vessel 104 for blending and/or conditioning process gases for delivery to showerhead 106. One or more mixing vessel inlet valves 120 may control introduction of process gases to mixing vessel 104. Particular reactants may be stored in liquid form prior to vaporization and subsequent delivery to process station 102 of a process chamber. The implementation of FIG. 1 includes a vaporization point 103 for vaporizing liquid reactant to be supplied to mixing vessel 104. In some implementations, vaporization point 103 may include a heated liquid injection module. In some other implementations, vaporization point 103 may include a heated vaporizer. In yet other implementations, vaporization point 103 may be eliminated from the process station. In some implementations, a liquid flow controller upstream of vaporization point 103 may be provided for controlling a mass flow of liquid for vaporization and delivery to process station 102.

Showerhead 106 may operate to distribute process gases and/or reactants (e.g., film precursors) toward substrate 112 at the process station, the flow of which may be controlled by one or more valves upstream from the showerhead (e.g., valves 120, 120A, 105). In the implementation depicted in FIG. 1, substrate 112 is depicted as located beneath showerhead 106, and is shown resting on a pedestal 108. Showerhead 106 may include any suitable shape and may include any suitable number and arrangement of ports for distributing process gases to substrate 112. In some implementations involving two or more stations, gas delivery system 101 includes valves or other flow control structures upstream from the showerhead, which can independently control the flow of process gases and/or reactants to each station so as to permit gas flow to one station while prohibiting gas flow to a second station. Furthermore, gas delivery system 101 may be configured to independently control process gases and/or reactants delivered to each station in a multi-station apparatus such that the gas composition provided to different stations is different; e.g., the partial pressure of a gas component may vary between stations at the same time.

In the implementation of FIG. 1, gas volume 107 is depicted as being located beneath showerhead 106. In some implementations, pedestal 108 may be raised or lowered to expose substrate 112 to gas volume 107 and/or to vary the size of gas volume 107. The separation between pedestal 108 and showerhead 106 is sometimes referred to as a “gap.” Optionally, pedestal 108 may be lowered and/or raised during portions of the deposition process to modulate process pressure, reactant concentration, etc., within gas volume 107. Showerhead 106 and pedestal 108 are depicted as being electrically coupled to RF signal generator 114 and matching network 116 for coupling power to a plasma generator. Thus, showerhead 106 may function as an electrode for coupling radio frequency power into process station 102. RF signal generator 114 and matching network 116 may be operated at any suitable RF power level, which may operate to form plasma having a desired composition of radical species, ions, and electrons. In addition, RF signal generator 114 may provide RF power having more than one frequency component, such as a low-frequency component (e.g., less than about 2 MHz) as well as a high frequency component (e.g., greater than about 2 MHz). In some implementations, plasma ignition and maintenance conditions are controlled with appropriate hardware and/or appropriate machine-readable instructions in a system controller which may provide control instructions via a sequence of input/output control instructions.

As described above in connection with FIG. 1, a process station may include a showerhead and a pedestal, each of which may be considered electrodes. As described above, an RF signal may be applied to one of the electrodes, such as the pedestal. In such an example, the showerhead may be considered an unpowered electrode. The showerhead may be considered as having an inductance, generally referred to herein as L_{shd}. The showerhead inductance may generally be within a range of 10 nH-50 nH. Due to the showerhead inductance, the impedance associated with the showerhead (generally referred to herein as Z_{shd}) is Z_{shd}=joL_{shd}. At relatively low RF frequencies, the effect of the showerhead inductance may have negligible effect on the impedance associated with the showerhead. Accordingly, the voltage across the showerhead may also be negligible. In other words, at relatively low RF frequencies, the showerhead may effectively be DC grounded thereby having the same potential as the chamber. However, at higher RF frequencies (e.g., above 20 MHz, above 30 MHz, above 40 MHz, or the like), the impedance associated with the showerhead may increase, thereby causing a corresponding increase in the voltage across the showerhead (generally referred to herein as V_{shd}) relative to the chamber. It should be understood that in cases in which the RF signal is applied to the showerhead, the pedestal may be considered the unpowered electrode. Similar to what is described above with respect to a voltage developing across the showerhead at higher RF frequencies in instances in which the showerhead is the unpowered electrode, a voltage may develop across the pedestal in instances in which the pedestal is the unpowered electrode.

The components of the reactor, including the pedestal, the showerhead, and plasma sustained between the pedestal and the showerhead may be represented as an equivalent circuit of resistors, inductors, and/or capacitors. In particular, the equivalent circuit may be a series RLC circuit. In an instance in which the pedestal is the powered electrode, the RLC circuit may include an RF signal generator electrically coupled to an inductor representing the pedestal feed hardware, a capacitor and resistor in series representing plasma sustained between the pedestal and the showerhead, and an inductor representing the showerhead. As discussed above, a voltage across the showerhead (V_{Shd}) may be affected by characteristics of an RF signal applied to the pedestal. A voltage at a top portion of the pedestal (generally referred to herein as V_{ped}), corresponding to a surface of the pedestal on which a substrate undergoing processing is positioned, may also be affected by characteristics of the RF signal. Moreover, because the circuit elements are coupled in series, the voltage across the showerhead (V_{shd}) may also impact the voltage at the top portion of the pedestal (V_{ped}). Accordingly, undesired voltage across the showerhead (e.g., due to the inductance of the showerhead) may cause undesired voltage changes at the surface of the pedestal, which may in turn cause undesired change in the plasma conditions within the reactor. For example, such undesired voltage changes across various components in the reactor may cause parasitic plasma. As a more particular example, such parasitic plasma may include plasma between the showerhead and the wall, under a portion of the pedestal, or the like. Moreover, such undesired voltage changes may create undesirable fabrication effects on a wafer undergoing processing within the reactor, such as non-uniform deposition, non-uniform etching, or the like. It should be understood that in embodiments in which the powered electrode is the showerhead, and in which the unpowered electrode is the pedestal, the RF signal generator may be electrically coupled to an inductor representing the showerhead.

FIG. 2 shows a schematic diagram that illustrates components of a reactor that utilizes a pedestal as a powered electrode represented as equivalent circuit elements in accordance with some embodiments. As illustrated, an RF generator 202 is represented by a current source 204. As described above in connection with FIG. 1, RF signal generator 202 may be configured to provide RF signals at one or more frequencies, including a low frequency (e.g., about 2 MHz) and/or a high frequency (e.g., above 2 MHz). RF signal generator 202 is electrically coupled to a pedestal 206. The stem of the pedestal is represented by an inductor 208 (referred to as L_{ped}). As shown in FIG. 2, a voltage at a top portion of pedestal 206 is generally referred to herein as V_{ped}. A plasma 210, when present, is sustained between pedestal 206 and a showerhead 216. Plasma 210 may be represented by a capacitor 212 (generally referred to herein as Cₚₗₐₛₘₐ) and a resistor 214 (generally referred to herein as Rₚₗₐₛₘₐ), in series. In general, Rₚₗₐₛₘₐ represents a plasma slab resistance, and Cₚₗₐₛₘₐ represents a plasma sheath capacitance. Showerhead 216, when fixed to a wall of the reactor (as in conventional setups), is represented by an inductor 220 (referred to herein as L_{Shd}), which is in turn coupled to ground (i.e., the station wall). This configuration is sometimes referred to as a “grounded showerhead configuration.” The voltage across the showerhead, V_{shd}, corresponds to the voltage at the node of the inductor 220 that is not grounded, as shown in FIG. 2.

In some implementations, a variable reactance element may be used to modulate one or more voltages associated with a station. Examples of variable reactance elements include a variable capacitor, a variable inductor, and a network that can allow different behaviors at different frequencies (e.g., at DC, harmonics at RF drive frequencies, and/or multiple RF drive frequencies) by providing different reactances for different frequencies through different reactance elements. In some embodiments, a variable reactance element may be operatively coupled to an unpowered electrode of the station. For example, in an instance in which the pedestal is the powered electrode of a station, a variable reactance element may be operatively coupled to the showerhead. As another example, in an instance in which the showerhead is the powered electrode, a variable reactance element may be operatively coupled to the pedestal.

Because the circuit elements representing various station components or regions (e.g., as shown in and described above in connection with FIG. 2) are generally coupled in series, varying a variable reactance element may modulate voltages throughout the station. For example, varying a reactance of a variable reactance element may cause changes in a voltage associated with a pedestal (e.g., V_{ped}, as shown in and described above in connection with FIG. 2) and/or a voltage across a showerhead (e.g., V_{shd}) as shown in and described above in connection with FIG. 2).

FIG. 3 shows a schematic diagram that illustrates components of the reactor of FIG. 2 and includes a variable reactance element operatively coupled to the showerhead (i.e., the unpowered electrode of the reactor of FIG. 2), in accordance with some implementations. As illustrated, a variable capacitor 302 is operatively coupled to showerhead 216. By tuning variable capacitor 302, the voltage across showerhead 216 (V_{shd}) and the voltage associated with the pedestal (V_{ped}) can be changed, or modulated.

As described above, modulation of a variable reactance element may cause voltage changes for one or more voltages associated with a station. The one or more voltages may include a voltage across a showerhead, a voltage at an upper or top portion of a pedestal (e.g., where a wafer resides during processing), or the like. Note that the voltage changes may occur whether the variable reactance element is operatively coupled to the showerhead (e.g., in cases in which the pedestal is the powered electrode), or whether the variable reactance element is operatively coupled to the pedestal (e.g., in cases in which the showerhead is the powered electrode).

It should be noted that changes in the one or more voltages may depend on characteristics of plasma present in the station. For example, as illustrated in and described above in connection with FIGS. 2 and 3, plasma may be represented by a resistor (Rₚₗₐₛₘₐ) and a capacitor (Cₚₗₐₛₘₐ) in series. Continuing with this example, the characteristics of the plasma may affect the values for the resistance and/or the capacitance that represent the plasma. The values of the resistance and/or the capacitance that represent the plasma may in turn affect the changes in the one or more voltages. In some implementations, values of Cₚₗₐₛₘₐ may range from about 200 pF to about 1200 pF, which may correspond to a plasma sheath thickness of about 0.25 millimeters to about 1.5 millimeters. In some implementations, a voltage in a particular region of the station may be modulated within a range that is at least partly dependent on a resistance associated with the plasma (Rₚₗₐₛₘₐ). For example, in some embodiments, larger voltage changes may be possible with a relatively lower plasma resistance (e.g., about 0.5 ohms, about 1 ohm, about 1.5 ohms, about 2 ohms, or the like) relative to higher plasma resistance (e.g., greater than about 9 ohms, greater than about 10 ohms, greater than about 15 ohms, or the like).

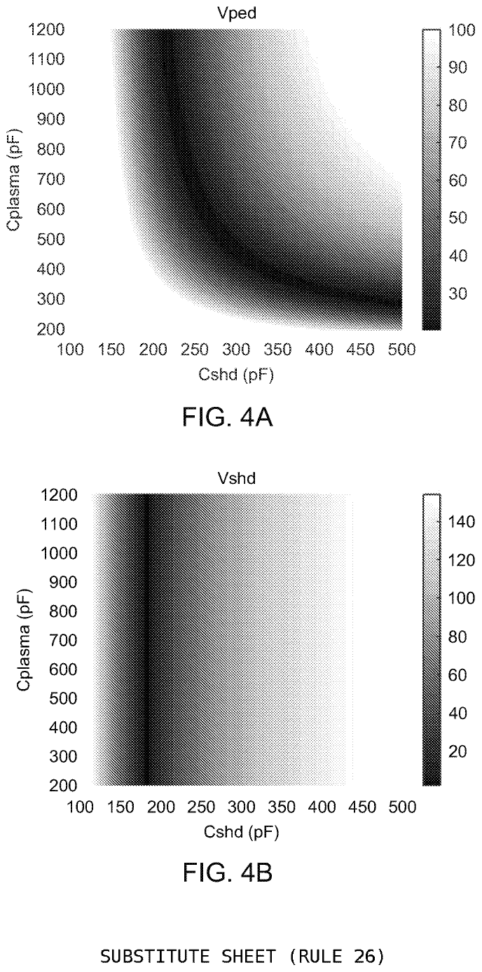

FIG. 4A illustrates a contour plot of voltage changes at a pedestal (V_{ped}) responsive to varying reactances of a variable capacitor operatively coupled to a showerhead of a station. As illustrated, the pedestal voltage may be able to be varied over a range from about 20 to 100 (using arbitrary voltage units). The contour plot of FIG. 4A was generated assuming a fixed plasma resistance of 1 ohm and for various plasma capacitances (as illustrated on the y-axis). The x-axis illustrates varying values of the variable showerhead capacitance. Note that, for a given plasma capacitance (e.g., 1200 pF), the pedestal voltage may be varied over the dynamic voltage range by tuning the showerhead capacitor from 100 pF to 500 pF.

FIG. 4B illustrates a contour plot of voltage changes at a showerhead (V_{shd}) responsive to varying reactances of the variable capacitor operatively coupled to the showerhead. In other words, FIGS. 4A and 4B both vary a reactance of a variable showerhead capacitor, but illustrate changes in voltages at different regions of the station (i.e., the pedestal in FIG. 4A, and the showerhead in FIG. 4B). Similar to what is described above in connection with FIG. 4A, the contour plot of FIG. 4A was generated assuming a fixed plasma resistance of 1 ohm and for various plasma capacitances (as illustrated on the y-axis). The x-axis illustrates varying values of the variable showerhead capacitance. Note that, for a given plasma capacitance (e.g., 1200 pF), the showerhead voltage may be varied over the dynamic voltage range by tuning the showerhead capacitor from 100 pF to 500 pF.

In some implementations, during and/or prior to performance of a plasma operation, one or more target voltages associated with components of a station in which the plasma operation is being performed or will be performed are determined. The one or more target voltages may be associated with a pedestal of the station (e.g., a top portion of the pedestal where a wafer resides during processing), a showerhead of the station, or the like. The plasma operation may be a plasma-based etch operation or a plasma-based deposition operation. In some embodiments, the one or more target voltages may be determined based on a target voltage indicated in a recipe to be implemented in the station. In some embodiments, a target voltage of the one or more target voltages may be 0 Volts, or another minimum voltage, for example, in a case in which a goal is to minimize a voltage across the showerhead. In some cases, target voltages may be specified for a particular component at multiple frequencies, for example, multiple RF drive frequencies, harmonics of multiple RF drive frequencies, DC, or the like. In some implementations, a target voltage for a particular component may be determined based on an estimate of near real-time or prevailing plasma characteristics (e.g., during performance of a plasma operation). In some embodiments, near real-time or prevailing plasma characteristics may be estimated or determined using an optical sensor (e.g., one or more camera devices) with a viewport directed into the station.

In some embodiments, a value of at least one variable reactance element associated with a component of the station may be determined based at least in part on the one or more target voltages. In some embodiments, the variable reactance element may be a variable inductor and/or a variable capacitor. In some implementations, the variable reactance element may be a network of reactance elements (e.g., multiple reactance elements) such that different reactances may be selected by selecting different nodes of the network, for example, at different frequencies. In some implementations, the variable reactance element may be a fixed hardware element that may be easily replaced in the field. Such fixed hardware elements may include capacitors, inductors, or the like which are relatively low-cost and/or easily replaced.

In some embodiments, the at least one variable reactance element may be associated with a particular component of the station. The component may correspond to the unpowered electrode of the station. For example, as described above in connection with FIG. 3, in an instance in which the pedestal is the powered electrode, the at least one variable reactance element may be operatively coupled to the showerhead. As another example, in an instance in which the showerhead is the powered electrode, the at least one variable reactance element may be operatively coupled to the pedestal.

In some embodiments, the value of the at least one variable reactance element may be determined using a look up table. For example, the one or more target voltages may be used as keys to a look up table to determine the value of the at least one variable reactance element that will yield voltages that are closer to the one or more target voltages relative to the prevailing voltage values. It should be noted that, in some cases, it may be possible to drive the voltage associated with a particular component to substantially match a target voltage associated with the component. For example, the voltage may be within a predetermined range (e.g., +/−1%, +/−5%, +/−10%, or the like) of the target voltage associated with the component. In other cases, it may only be possible to drive the voltage associated with a particular component to be closer to the target voltage relative to a prevailing voltage associated with the component. Moreover, it should be noted that, in instances in which multiple target voltages are utilized (e.g., a target voltage for a showerhead and a target voltage for a pedestal), it may not be possible to match the multiple target voltages by tuning the at least one variable reactance element. In such cases, a value of the at least one reactance element may be selected that optimizes values of the multiple voltages. Additionally or alternatively, a value of the at least one reactance element may be selected that prioritizes a subset of the one or more target voltages. By way of example, in an instance in which the target voltages include a pedestal voltage and a showerhead voltage, one or the other may be prioritized in determining a value of the at least one variable reactance element to drive the voltage of the prioritized component voltage toward the corresponding target voltage, with less consideration for the other component voltage.

After determining the value of the at least one variable reactance element, the at least one variable reactance element may be tuned or actuated to have the determined value. For example, a stepper motor may be utilized to cause the at least one variable reactance element to have the determined value. As a more particular example, a stepper motor may rotate plates of a variable capacitor to achieve the determined reactance value. As another example, in an instance in which the at least one variable reactance element includes a variable inductor, a solid core within a solenoid may be moved or positioned (e.g., using a stepper motor) to achieve a target inductance.

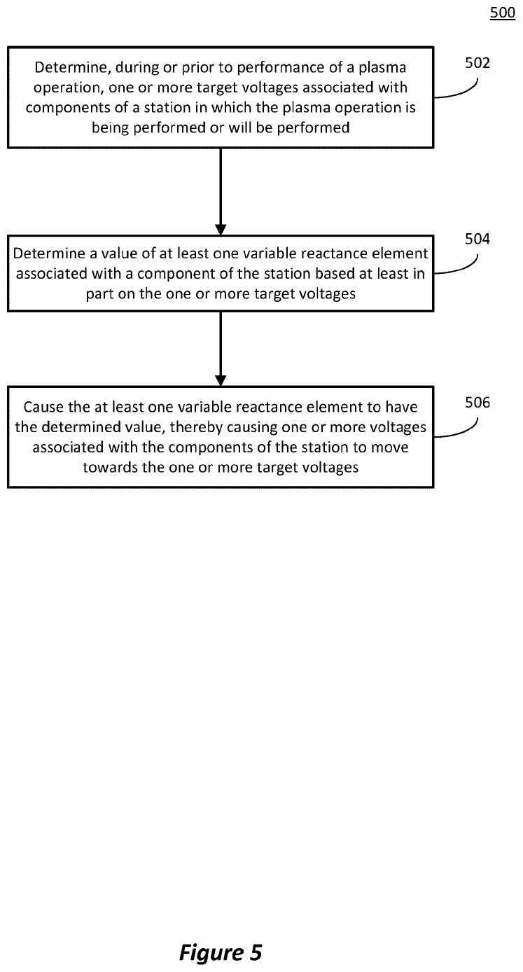

FIG. 5 is a flowchart of an example process 500 for tuning a variable reactance element to modulate voltages associated with a station in which a plasma operation is being performed or will be performed. In some implementations, blocks of process 500 may be performed by a controller or a processor associated with the station or with a process chamber associated with the station. In some embodiments, blocks of process 500 may be performed in an order other than what is shown in FIG. 5. In some implementations, two or more blocks of process 500 may be executed substantially in parallel. In some implementations, one or more blocks of process 500 may be omitted.

Process 500 can begin at 502 by determining, during or prior to performance of a plasma operation, one or more target voltages associated with components of a station in which the plasma operation is being performed or will be performed. The plasma operation may be a plasma-based etch operation or a plasma-based deposition operation. The one or more voltages may be associated with a showerhead of the station, a pedestal of the station (e.g., a top portion of the pedestal where a wafer resides during processing), or the like. The one or more target voltages may be determined based on a recipe that is being implemented or is to be implemented in the station. For example, the recipe may specify the one or more target voltages. In some embodiments, the one or more target voltages may be based on a determination of prevailing plasma characteristics of a plasma within the station (e.g., during performance of a plasma operation). The prevailing plasma characteristics may indicate plasma uniformity or plasma centroid location within the station or within a region of the station. In some embodiments, the plasma characteristics may be determined based on optical data obtained from one or more optical sensors of the station (e.g., camera sensors). In some implementations, the one or more target voltages may be determined to modify plasma characteristics toward desired or optimal plasma characteristics. In some embodiments, at least one target voltage may be 0, or an otherwise minimal voltage value. For example, a target voltage associated with an unpowered electrode of the station may be determined to be 0 at particular frequencies such that the unpowered electrode may be considered to be DC-grounded when the target voltage is achieved.

At 504, process 500 can determine a value of at least one variable reactance element associated with a component of the station based at least in part on the one or more target voltages. For example, as described above, process 500 can use the one or more target voltages as a key to a look up table to identify values of the at least one variable reactance element suitable to drive the voltages of the components of the station toward the one or more target voltages. In some implementations, the value of the at least one reactance element may be determined by considering multiple target voltages associated with multiple components. Additionally or alternatively, in some implementations, the value of the at least one reactance element may be determined by prioritizing one target voltages associated with a single component of the station. As described above, the at least one variable reactance element may include a variable capacitor, a variable inductor, and/or a variable reactance network that may be selectively tuned for different frequencies. The at least one variable reactance element may be associated with an unpowered electrode of the station.

At 506, process 500 can cause the at least one variable reactance element to have the determined value, thereby causing one or more voltages associated with the components of the station to move towards the one or more target voltages. For example, process 500 can cause a stepper motor to actuate plates of a variable capacitor to achieve a target reactance of the variable capacitor. As another example, process 500 can actuate a core within a solenoid to achieve a target reactance of a variable inductor.

It should be noted that, in some implementations, blocks of process 500 may be looped through multiple times. For example, process 500 may be performed during or prior to each step of a recipe. As another example, process 500 may be performed after particular process conditions have been implemented (e.g., as specified in a recipe) to perform further modulation of a process, i.e., by modulating voltages of various components, after other process conditions have been locked in or fixed.

### Context for Disclosed Computational Embodiments

Certain embodiments disclosed herein relate to computational systems for modulating voltages during plasma operations.

Many types of computing systems having any of various computer architectures may be employed as the disclosed systems for implementing algorithms as described herein. For example, the systems may include software components executing on one or more general purpose processors or specially designed processors such as Application Specific Integrated Circuits (ASICs) or programmable logic devices (e.g., Field Programmable Gate Arrays (FPGAs)). Further, the systems may be implemented on a single device or distributed across multiple devices. The functions of the computational elements may be merged into one another or further split into multiple sub-modules.

In some embodiments, code executed during generation or execution of a technique described herein on an appropriately programmed system can be embodied in the form of software elements which can be stored in a nonvolatile storage medium (such as optical disk, flash storage device, mobile hard disk, etc.), including a number of instructions for making a computer device (such as personal computers, servers, network equipment, etc.).

At one level a software element is implemented as a set of commands prepared by the programmer/developer. However, the module software that can be executed by the computer hardware is executable code committed to memory using “machine codes” selected from the specific machine language instruction set, or “native instructions,” designed into the hardware processor. The machine language instruction set, or native instruction set, is known to, and essentially built into, the hardware processor(s). This is the “language” by which the system and application software communicates with the hardware processors. Each native instruction is a discrete code that is recognized by the processing architecture and that can specify particular registers for arithmetic, addressing, or control functions; particular memory locations or offsets; and particular addressing modes used to interpret operands. More complex operations are built up by combining these simple native instructions, which are executed sequentially, or as otherwise directed by control flow instructions.

The inter-relationship between the executable software instructions and the hardware processor is structural. In other words, the instructions per se are a series of symbols or numeric values. They do not intrinsically convey any information. It is the processor, which by design was preconfigured to interpret the symbols/numeric values, which imparts meaning to the instructions.

The methods and techniques used herein may be configured to execute on a single machine at a single location, on multiple machines at a single location, or on multiple machines at multiple locations. When multiple machines are employed, the individual machines may be tailored for their particular tasks. For example, operations requiring large blocks of code and/or significant processing capacity may be implemented on large and/or stationary machines.

In addition, certain embodiments relate to tangible and/or non-transitory computer readable media or computer program products that include program instructions and/or data (including data structures) for performing various computer-implemented operations. Examples of computer-readable media include, but are not limited to, semiconductor memory devices, phase-change devices, magnetic media such as disk drives, magnetic tape, optical media such as CDs, magneto-optical media, and hardware devices that are specially configured to store and perform program instructions, such as read-only memory devices (ROM) and random access memory (RAM). The computer readable media may be directly controlled by an end user or the media may be indirectly controlled by the end user. Examples of directly controlled media include the media located at a user facility and/or media that are not shared with other entities. Examples of indirectly controlled media include media that is indirectly accessible to the user via an external network and/or via a service providing shared resources such as the “cloud.” Examples of program instructions include both machine code, such as produced by a compiler, and files containing higher level code that may be executed by the computer using an interpreter.

In various embodiments, the data or information employed in the disclosed methods and apparatus is provided in an electronic format. Such data or information may include various coefficients to be used in calculations, and the like. As used herein, data or other information provided in electronic format is available for storage on a machine and transmission between machines. Conventionally, data in electronic format is provided digitally and may be stored as bits and/or bytes in various data structures, lists, databases, etc. The data may be embodied electronically, optically, etc.

System software typically interfaces with computer hardware and associated memory. In some embodiments, the system software includes operating system software and/or firmware, as well as any middleware and drivers installed in the system. The system software provides basic non-task-specific functions of the computer. In contrast, the modules and other application software are used to accomplish specific tasks. Each native instruction for a module is stored in a memory device and is represented by a numeric value.

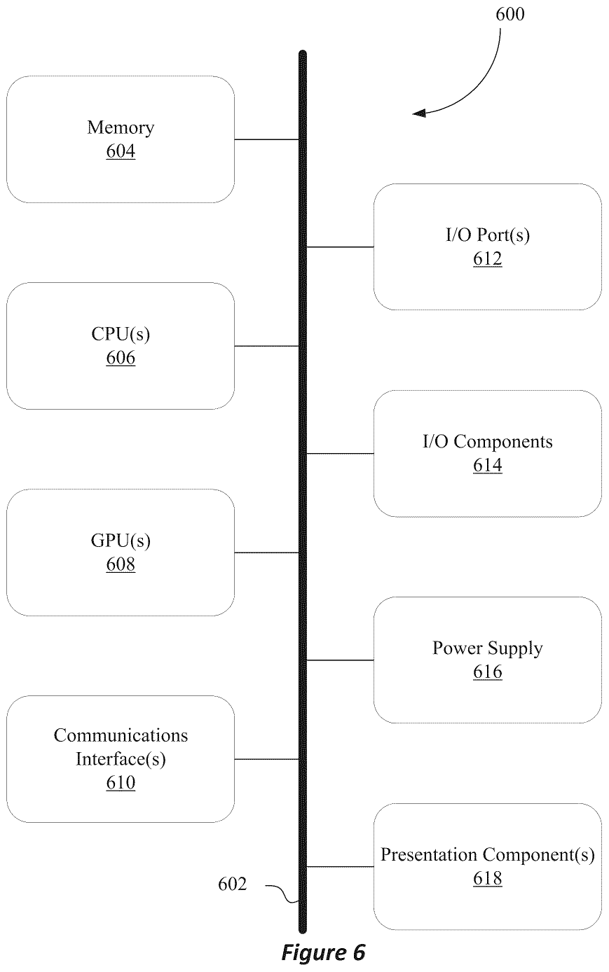

FIG. 6 is a block diagram of an example of the computing device 600 suitable for use in implementing some embodiments of the present disclosure. For example, device 600 may be suitable for implementing some or all functions of image analysis logic disclosed herein.

Computing device 600 may include a bus 602 that directly or indirectly couples the following devices: memory 604, one or more central processing units (CPUs) 606, one or more graphics processing units (GPUs) 608, a communication interface 1010, input/output (I/O) ports 612, input/output components 614, a power supply 616, and one or more presentation components 618 (e.g., display(s)). In addition to CPU 606 and GPU 608, computing device 600 may include additional logic devices that are not shown in FIG. 6, such as but not limited to an image signal processor (ISP), a digital signal processor (DSP), an ASIC, an FPGA, or the like.

Although the various blocks of FIG. 6 are shown as connected via the bus 602 with lines, this is not intended to be limiting and is for clarity only. For example, in some embodiments, a presentation component 618, such as a display device, may be considered an I/O component 614 (e.g., if the display is a touch screen). As another example, CPUs 606 and/or GPUs 608 may include memory (e.g., the memory 604 may be representative of a storage device in addition to the memory of the GPUs 608, the CPUs 606, and/or other components). In other words, the computing device of FIG. 6 is merely illustrative. Distinction is not made between such categories as “workstation,” “server,” “laptop,” “desktop,” “tablet,” “client device,” “mobile device,” “hand-held device,” “electronic control unit (ECU),” “virtual reality system,” and/or other device or system types, as all are contemplated within the scope of the computing device of FIG. 6.

Bus 602 may represent one or more busses, such as an address bus, a data bus, a control bus, or a combination thereof. The bus 1002 may include one or more bus types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus.

Memory 604 may include any of a variety of computer-readable media. The computer-readable media may be any available media that can be accessed by the computing device 600. The computer-readable media may include both volatile and nonvolatile media, and removable and non-removable media. By way of example, and not limitation, the computer-readable media may comprise computer-storage media and/or communication media.

The computer-storage media may include both volatile and nonvolatile media and/or removable and non-removable media implemented in any method or technology for storage of information such as computer-readable instructions, data structures, program modules, and/or other data types. For example, memory 1004 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 1000. As used herein, computer storage media does not comprise signals per se.

The communication media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the communication media may include wired media such as a wired network or direct-wired connection, and wireless media such as acoustic, RF, infrared and other wireless media. Combinations of any of the above should also be included within the scope of computer-readable media.

CPU(s) 606 may be configured to execute the computer-readable instructions to control one or more components of the computing device 600 to perform one or more of the methods and/or processes described herein. CPU(s) 606 may each include one or more cores (e.g., one, two, four, eight, twenty-eight, seventy-two, etc.) that are capable of handling a multitude of software threads simultaneously. CPU(s) 606 may include any type of processor and may include different types of processors depending on the type of computing device 600 implemented (e.g., processors with fewer cores for mobile devices and processors with more cores for servers). For example, depending on the type of computing device 600, the processor may be an ARM processor implemented using Reduced Instruction Set Computing (RISC) or an x86 processor implemented using Complex Instruction Set Computing (CISC). Computing device 600 may include one or more CPUs 606 in addition to one or more microprocessors or supplementary co-processors, such as math co-processors.

GPU(s) 608 may be used by computing device 600 to render graphics (e.g., 3D graphics). GPU(s) 608 may include many (e.g., tens, hundreds, or thousands) of cores that are capable of handling many software threads simultaneously. GPU(s) 608 may generate pixel data for output images in response to rendering commands (e.g., rendering commands from CPU(s) 606 received via a host interface). GPU(s) 608 may include graphics memory, such as display memory, for storing pixel data. The display memory may be included as part of memory 604. GPU(s) 608 may include two or more GPUs operating in parallel (e.g., via a link). When combined, each GPU 608 can generate pixel data for different portions of an output image or for different output images (e.g., a first GPU for a first image and a second GPU for a second image). Each GPU can include its own memory or can share memory with other GPUs.

In examples where the computing device 600 does not include the GPU(s) 608, the CPU(s) 606 may be used to render graphics.

Communication interface 610 may include one or more receivers, transmitters, and/or transceivers that enable computing device 600 to communicate with other computing devices via an electronic communication network, included wired and/or wireless communications. Communication interface 610 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet), low-power wide-area networks (e.g., LoRaWAN, SigFox, etc.), and/or the internet.

I/O ports 612 may enable the computing device 600 to be logically coupled to other devices including I/O components 614, presentation component(s) 618, and/or other components, some of which may be built in to (e.g., integrated in) computing device 600. Illustrative I/O components 614 include a microphone, mouse, keyboard, joystick, track pad, satellite dish, scanner, printer, wireless device, etc. I/O components 614 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of computing device 600. Computing device 600 may be include depth cameras, such as stereoscopic camera systems, infrared camera systems, RGB camera systems, touchscreen technology, and combinations of these, for gesture detection and recognition. Additionally, computing device 600 may include accelerometers or gyroscopes (e.g., as part of an inertia measurement unit (IMU)) that enable detection of motion. In some examples, the output of the accelerometers or gyroscopes may be used by computing device 600 to render immersive augmented reality or virtual reality.

Power supply 616 may include a hard-wired power supply, a battery power supply, or a combination thereof. Power supply 616 may provide power to computing device 600 to enable the components of computing device 600 to operate.

Presentation component(s) 618 may include a display (e.g., a monitor, a touch screen, a television screen, a heads-up-display (HUD), other display types, or a combination thereof), speakers, and/or other presentation components. Presentation component(s) 618 may receive data from other components (e.g., GPU(s) 608, CPU(s) 606, etc.), and output the data (e.g., as an image, video, sound, etc.).

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

### Conclusion

In the description, numerous specific details were set forth in order to provide a thorough understanding of the presented embodiments. The disclosed embodiments may be practiced without some or all of these specific details. In other instances, well-known process operations were not described in detail to not unnecessarily obscure the disclosed embodiments. While the disclosed embodiments were described in conjunction with the specific embodiments, it will be understood that the specific embodiments are not intended to limit the disclosed embodiments.

Unless otherwise indicated, the method operations and device features disclosed herein involves techniques and apparatus commonly used in metrology, semiconductor device fabrication technology, software design and programming, and statistics, which are within the skill of the art.

Unless defined otherwise herein, all technical and scientific terms used herein have the same meaning as commonly understood by one of ordinary skill in the art. Various scientific dictionaries that include the terms included herein are well known and available to those in the art. Although any methods and materials similar or equivalent to those described herein find use in the practice or testing of the embodiments disclosed herein, some methods and materials are described.

Numeric ranges are inclusive of the numbers defining the range. It is intended that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

The headings provided herein are not intended to limit the disclosure.

As used herein, the singular terms “a,” “an,” and “the” include the plural reference unless the context clearly indicates otherwise. The term “or” as used herein, refers to a non-exclusive or, unless otherwise indicated.

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware-for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

1. A system, comprising:
a process chamber configured for performing a semiconductor fabrication process comprising a plasma-based operation;
at least one variable reactance element operatively coupled to an unpowered electrode of the process chamber; and
a controller configured to:
determine, during or prior to performance of the plasma-based operation, one or more target voltages associated with one or more components of the process chamber,
determine a value of the at least one variable reactance element based at least in part on the one or more target voltages, and
cause the at least one variable reactance element to have the determined value, wherein causing the at least one variable reactance element to have the determined value causes one or more voltages associated with the one or more components of the process chamber to move towards the one or more target voltages.

2. The system of claim 1, wherein the unpowered electrode of the process chamber comprises a showerhead of the process chamber, and wherein the at least one variable reactance element is electrically connected to the showerhead or is disposed in a showerhead.

3. The system of claim 1, wherein the unpowered electrode of the process chamber is a pedestal of the process chamber, wherein the at least one variable reactance element is electrically connected to or is disposed in the pedestal of the process chamber.

4. The system of claim 1, wherein causing the one or more voltages associated with the one or more components of the process chamber to move towards the one or more target voltages reduces a likelihood of parasitic plasma within the process chamber.

5. The system of claim 1, wherein at least one of the one or more target voltages is a voltage associated with an unpowered showerhead of the process chamber.

6. The system of claim 1, further comprising a pedestal configured to support a wafer undergoing the semiconductor fabrication process, and wherein at least one of the one or more target voltages is a voltage at a location proximate to a resting position of the wafer.

7. The system of claim 6, wherein causing the at least one variable reactance element to have the determined value causes the voltage at the location proximate to the resting position of the wafer to be substantially lower than a voltage at the location prior to causing the at least one variable reactance element to have the determined value.

8. The system of claim 6, further comprising a Radio-Frequency (RF) generator operatively coupled to the pedestal.

9. The system of claim 1, wherein the at least one variable reactance element comprises a variable capacitor.

10. The system of claim 9, further comprising a stepper motor operatively coupled to the variable capacitor, and wherein the controller is configured to cause the variable capacitor to have the determined value by actuating the stepper motor.

11. The system of claim 9, wherein the value of the variable capacitor is determined based on an inductance associated with the unpowered electrode.

12. The system of claim 1, wherein the at least one variable reactance element comprises a variable inductor.

13. The system of claim 1, wherein the at least one variable reactance element comprises a network configured to provide different reactances for different frequencies.

14. The system of claim 13, wherein the different frequencies comprise: DC, a plurality of RF drive frequencies, a plurality of harmonics of one or more RF drive frequencies, or any combination thereof.

15. The system of claim 1, wherein the at least one variable reactance element comprises a replaceable hardware element.

16. The system of claim 1, wherein the plasma operation is a plasma-based etch operation or a plasma-based deposition operation.

17. A method for modulating voltages of process chambers, the method comprising:
determining, during or prior to performance of a plasma-based operation within a process chamber, one or more target voltages associated with one or more components of the process chamber, the process chamber comprising an unpowered electrode;
determining a value of at least one variable reactance element operatively coupled to the unpowered electrode; and
causing the at least one variable reactance element to have the determined value, wherein causing the at least one variable reactance element to have the determined value causes one or more voltages associated with the one or more components of the process chamber to move towards the one or more target voltages.

18. The method of claim 17, wherein determining the value of the at least one variable reactance element comprises utilizing the one or more target voltages as key values to a look up table to identify the value of the at least one variable reactance element that causes the one or more voltages associated with the one or more components to be within a predetermined range of the one or more target voltages.

19. The method of claim 17, wherein determining the value of the at least one variable reactance element is based on a circuit model of at least a portion of the process chamber, wherein the circuit model includes the at least one variable reactance element.

20. The method of claim 19, wherein the circuit model comprises one or more circuit elements associated with a plasma formed in the process chamber.

21. The method of claim 20, wherein the one or more circuit elements associated with the plasma comprise a resistor representing a plasma resistance and a capacitor representing a capacitance associated with a plasma sheath.

22. The method of claim 19, wherein the at least one variable reactance element comprises a variable capacitor, and wherein the circuit model comprises the variable capacitor coupled in series to an inductor representing an inductance of the unpowered electrode.

23. The method of claim 22, wherein the value of the variable capacitor is determined as a value that causes an impedance associated with the variable capacitor to substantially cancel an impedance associated with the inductor representing the inductance of the unpowered electrode.

24. The method of claim 17, wherein the unpowered electrode comprises a pedestal of the process chamber.

25. The method of claim 17, wherein the at least one variable reactance element comprises a variable inductor.

26. The method of claim 17, wherein the value of the at least one variable reactance element is determined based at least in part on plasma characteristics determined based on optical data captured from an optical sensor.

27. The method of claim 17, wherein the value of the at least one variable reactance element is determined based at least in part on plasma characteristics determined based on electrical power, voltage, current, and/or phase measurements of RF signal(s) measured within: one or more regions of the process chamber; an RF power delivery system; or any combination thereof.

28. The method of claim 17, wherein the value of the at least one variable reactance element is determined based at least in part on plasma characteristics determined based on DC bias signals measured on one or more of: a powered electrode, or on the unpowered electrode.

29. The method of claim 17, wherein the value of the at least one variable reactance element is determined based at least in part on plasma characteristics determined based on electrical plasma diagnostics in the process chamber.
